(19) United States
(12) Patent Application Publication
(10) Pub. No.: US 2022/0373579 A1
(43) Pub. Date: Nov. 24, 2022

(54) RESIDUAL CURRENT DETECTION METHOD BASED ON MAGNETIC CORE WORKING STATE SWITCHING

(71) Applicant: QINGDAO TOPSCOMM COMMUNICATION CO., LTD, Qingdao, Shandon (CN)

(72) Inventors: Zean JIANG, Qingdao, Shandong (CN); Jianhua WANG, Qingdao, Shandong (CN); Zhen LIU, Qingdao, Shandong (CN)

(73) Assignee: QINGDAO TOPSCOMM COMMUNICATION CO., LTD, Qingdao, Shandong (CN)

(21) Appl. No.: 17/767,455

(22) PCT Filed: Sep. 30, 2020
(86) PCT No.: PCT/CN2020/119323

§ 371 Date: Apr. 8, 2022

(30) Foreign Application Priority Data
Oct. 9, 2019 (CN) 201910955505.6

(51) Int. Cl. G01R 15/18; G01R 31/52

(52) U.S. Cl. CPC G01R 15/183; G01R 31/52

(57) ABSTRACT

A method includes: step 1: configuring a detection state to be a pure induction mode with no voltage, keeping this mode for t1ms; step 2: configuring the detection state to be a mode of positive and negative saturation excitation square waves, keeping this mode for t2 ms; step 3: when a duration of each mode ends, outputting a characteristic quantity based on sampling data through an algorithm module, and processing the characteristic quantity by a software to complete a state determination; and step 4: in case of a sudden large current, adjusting the detection state to a new detection mode, to respond to the sudden large current, and the software performing process after data collection is completed and a process performed by the algorithm module is completed.

This application claims priority to Chinese Patent Application No. 201910955505.6, titled “COMPLICATED RESIDUAL CURRENT DETECTION METHOD BASED ON MAGNETIC CORE WORKING STATE SWITCHING”, filed on Oct. 9, 2019 with the China National Intellectual Property Administration, which is incorporated herein by reference in its entirety.

### FIELD

The present disclosure belongs to the field of leakage detection, and mainly relates to a method for detecting a residual current based on switching of working states of a magnetic core.

### BACKGROUND

With the development of economy, the power industry develops rapidly, types of various household appliances are increasing rich. Therefore, how to ensure electricity safety of household becomes particularly important. It is desirable to detect a variety of complex wave signals, including an alternating current, a direct current, a high-frequency signal, or the like. An alternating current residual current is extremely dangerous to the person, ventricular tremor may be caused at 50 mA/s. With the increase in the type of household appliances, it is also important to detect a direct current residual current. At present, the direct current is widely used, including direct current charging pile, variable frequency motor, etc., household appliance, such as certain types of notebook, microwave oven, washing machine. Therefore, there is an urgent need for high-precision detection of the alternating current residual current, the direct current residual current and a complex waveform.

Currently, there are products for residual current detection of type B and higher specification on the market, and electromagnetic current transformer, Hall current sensor and magnetic modulation current transformer, etc. are mostly used for residual current detection in which there are disadvantages, such as low detection precision and inability to cover all residual current waveforms. Therefore, it is desirable to develop a method that can effectively solve the above two problems.

### SUMMARY

In the present disclosure, for the above problems and in order to overcome the disadvantages of the conventional technology, a method for detecting a residual current based on switching of working states of a magnetic core is provided, in which the magnetic core is made of ferrite, and by the means of combining a voltage excitation mode with a pure induction mode, data is processed in a full electronic manner, which effectively solves the two problems, that is, all types of residual current are covered and a high-precision determination is achieved.

The present disclosure relates to a technology of detecting a complex residual current by using different responses of the magnetic core to the alternating current residual current and the direct current residual current in different regions of a magnetization curve and switching the working state. A leakage test is performed by detecting the residual current in the line, and the values of different types of residual currents are calculated through secondary algorithm analysis and the residual currents are determined by software, so as to achieve the protection against leakage.

In the present disclosure, a residual current transformer of two-phase coil is used as a detection device. As shown in FIG. 1, the working state of a detection winding is controlled by a chip, so as to detect different types of residual current. The alternating current residual current is an alternating signal, so a sensing signal may be generated through the coil. At this time, an undistorted alternating current signal can be sensed by using a linear region of the magnetic core. The measuring range of the detectable signal in the linear region meets the requirements of the national standard, which has be verified by calculation, and the signal exceeding the range may be directly determined as an over threshold signal; the direct current residual current is considered to be constant current when it exists, so a constant magnetic field is generated. At this time, the coil cannot be used for directly sensing the direct current magnetic field, but the direct current may correspond to a sensing signal in a nonlinear region of the hysteresis loop. Therefore, in the case of measuring the direct current, the signal acts on two saturation regions of the hysteresis loop alternately by using the positive and negative excitation square wave, different direct current may generate different responses in different regions, and the direct current detection can be completed by means of algorithm analysis and processing.

By using the linear region of the hysteresis loop of ferrite, when there is an alternating signal, the corresponding signal may be sensed by a secondary side, and the amplitude is inversely proportional to the number of coil turns. Since the linear region of ferrite is relatively wide, it has better characteristics of measuring the alternating current residual current. For 50 Hz power frequency signal, due to the low frequency, the amplitude of the sensing signal may become smaller, but the difference can be compensated by software compensation. Other high-frequency signals can be sensed in the linear region, and the effect of sensing is only related to the material characteristics, and the ferrite parameters can be customized to meet the performance requirements of high-frequency alternating current detection.

Using the characteristics of the hysteresis loop of ferrite, the direct current signal is not sensitive to the linear region, and the same principle is used in the saturation region, but there is a sensing value for direct current in the nonlinear region. The detection of the direct current residual current can be completed by the means of value change in the nonlinear region. A saturation excitation square wave has to be a bipolar square wave, and the chip can only output a unipolar square wave. In order to realize the bipolar square wave excitation to the magnetic core and ensure that the magnetic core can enter the saturation region bidirectionally, the unipolar square wave may be converted into the bipolar square wave through an H-bridge. When the magnetic core enters saturation at half wave, a reverse square wave excitation is applied immediately, that is, the reverse magnetic field of the same size is generated, and at this time, the winding changes from a magnetic saturation region on one side to a magnetic saturation region on the other side. Different direct current leakage values make the time to reach the number of ampere turns of saturation different and the corresponding currents different. The difference of different direct current residual currents can be extracted from the sampling of the sampling resistor, and the corresponding direct current leakage value is obtained by means of algorithm analysis.

### BRIEF DESCRIPTION OF THE DRAWINGS

FIG. 1 is a schematic diagram of the working principle of a residual current transformer;

FIG. 2 is a schematic diagram of a simplified model of the detection device;

FIG. 3 is a schematic diagram of three-state switching working in different regions of the hysteresis loop;

FIG. 4 is a schematic diagram of a simplified model of the hysteresis loop of ferrite;

FIG. 5 is a diagram showing the effect of direct current leakage using excitation square wave;

FIG. 6 is a diagram showing direct current residual current data;

FIG. 7 is a diagram showing alternating current residual current data.

### DETAILED DESCRIPTION

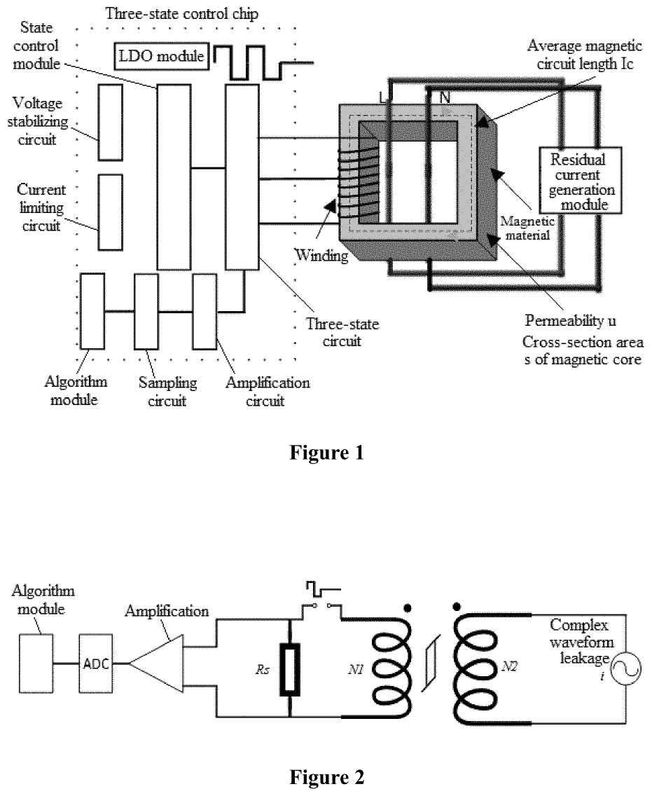

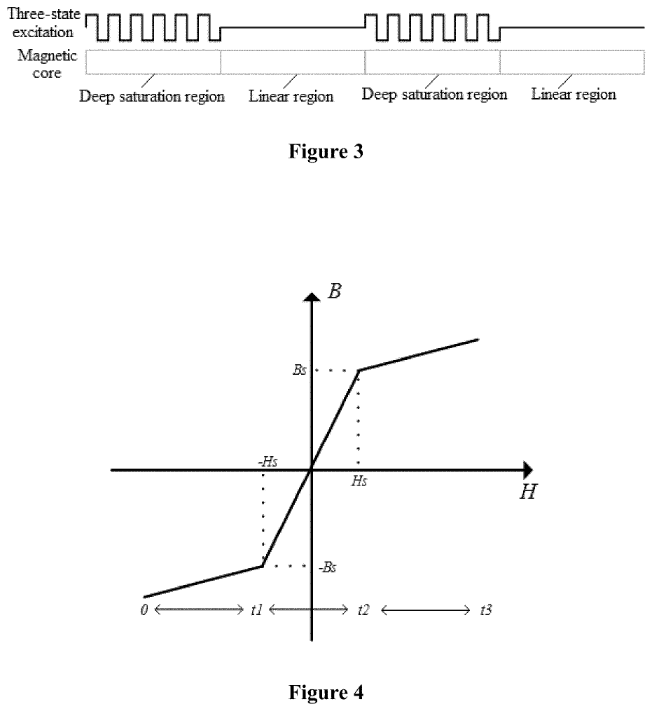

The technology of performing complex residual current detection by using the three-state switching of different magnetic core working states proposed in the present disclosure is described below in combination with FIGS. 1 to 7, so as to set forth the technical solution of the present disclosure in detail.

In the present disclosure, a ferrite residual current transformer is used as the detection device to complete the detection of a complex residual current through three-state switching control. As shown in FIG. 2, in case of detecting an alternating current, a state control module controls a circuit to work in a pure induction mode with no voltage. A current signal of an alternating residual current may be sensed by a coil by using the characteristics of a linear region of a magnetic core, and the current signal is collected through a sampling resistor.

In case of detecting an alternating current, the magnetic core works in the linear region.

According to the ampere circuital theorem, the magnetic field strength H is:

$$H = \frac{{N}_{1} \cdot {I}_{a c} + {N}_{2} \cdot {I}_{d c}}{l}$$

when the magnetic core works in the linear region, the permeability u is almost constant, the magnetic induction intensity B is:

$$B = {μ}_{l} \cdot H = {μ}_{l} \cdot \frac{{N}_{1} \cdot {I}_{a c} + {N}_{2} \cdot {I}_{d c}}{l}$$

and the induced electromotive force E is:

$$E = \frac{d ϕ}{d t} = \frac{d B \cdot S}{d t} = \frac{d ( {μ}_{l} \cdot \frac{{N}_{1} \cdot {I}_{a c} + {N}_{2} \cdot {I}_{d c}}{l} )}{dt} = \frac{{μ}_{l} \cdot {N}_{1}}{l} \cdot \frac{{dI}_{a c}}{d t}$$

From the above formulas, it may be inferred that when the magnetic core works in the linear region, the signal is sensitive to an alternating current signal and not sensitive to a direct current signal, so it is considered that the sensing signal is an alternating current signal.

When the signal passes through a nonlinear region, the permeability is changing, and when the excitation amplitude changes with time, the permeability may be regarded as a time-varying parameter μ(t). At this time, the sensing signal of the coil may be expressed as:

$$\begin{matrix}E = \frac{d ϕ}{dt} = \frac{d B \cdot S}{dt} \\ = \frac{d ( μ ( t ) \cdot \frac{{N}_{1} \cdot {I}_{a c} + {N}_{2} \cdot {I}_{d c}}{l} )}{d t} \\ = \frac{μ ( t ) \cdot {N}_{1}}{l} \cdot \frac{{dI}_{a c}}{d t} + \frac{{N}_{1} \cdot {I}_{a c}}{l} \cdot \frac{d μ ( t )}{d t} + \frac{{N}_{2} \cdot {I}_{d c}}{l} \cdot \frac{d μ ( t )}{d t}\end{matrix}$$

From the above formula, it may be analyzed that since the permeability μ(t) is changing when the magnetic core works in the nonlinear region, in the nonlinear region, a signal can be sensed from the direct current. Using the change in the nonlinear region, the direct current signal can be detected and determined by means of algorithm extraction and analysis.

When the excitation signal makes the magnetic core work in the saturation region, the excitation signal enters the deep saturation. At this time, the signal can completely reflect all the characteristics of the hysteresis loop. When the signal enters a deep saturation region, there is no sensing signal since the permeability is approximately equal to 0, but due to the existence of the excitation square wave, the inductor in the circuit has no impeding effect at this time, which is equivalent to a small resistance voltage divider. Therefore, the signal collected by the sampling resistor has a constant voltage value approximate to the amplitude of the excitation square wave.

If the alternating current residual current is large enough and the pure induction mode is used to make the magnetic core work into the saturation region, the alternating current signal may cover all regions of the hysteresis loop, and the sensing waveforms of signals in different regions may have different responses. In the linear region, the alternating current signal may be still sensed. In the nonlinear region, the signal may be superimposed with even harmonics, and in the deep saturation region, there is no sensing signal, and the signal may decay.

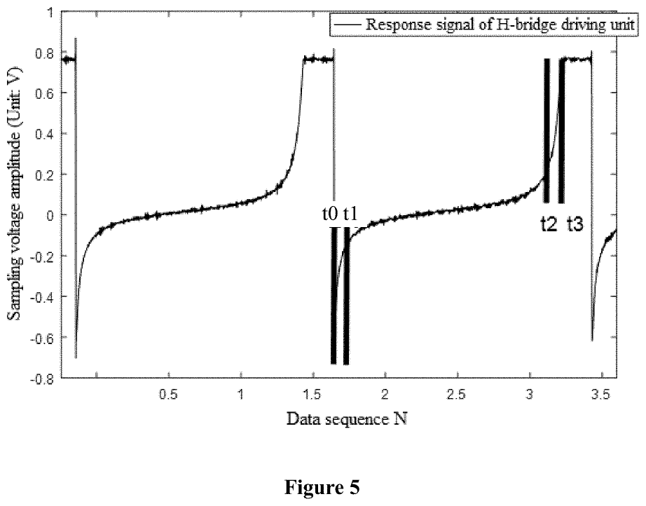

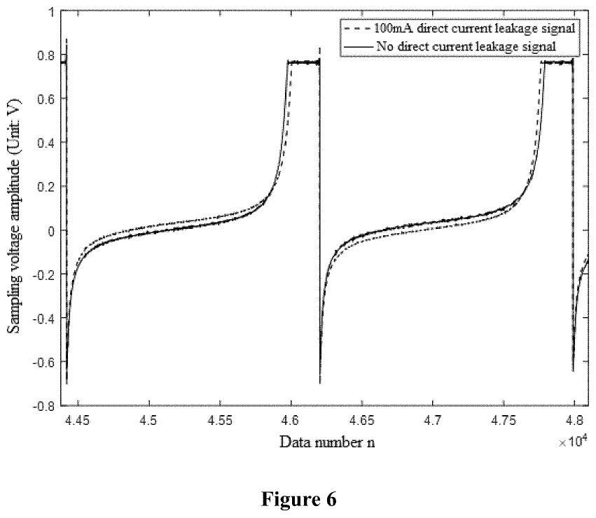

In case of detecting a direct current, positive and negative saturation excitation signals are output by the state control module, and the frequency of the square wave signal is adjustable. The charging time required to reach saturation is calculated according to the number of ampere turns of saturation. The period of the square wave signal is controlled to be greater than or equal to the sum of the bidirectional charging time, and the signal can reach the bidirectional deep saturation region of the magnetic core within the period. As shown in the simplified model of the magnetization curve in FIG. 4, in the time period of 0˜t1, the permeability is small, the coil has small impeding effect, and the response of the excitation signal changes quickly; in the time period of t1˜t2, the permeability is considered to be the largest, and there may be a process that the impeding changes; in the time period of t2˜t3, since the permeability changes from large to small, the inductive reactance returns to a small value, the impeding effect becomes small, and the response signal changes rapidly; after t3, the coil enters the deep saturation region and the signal collected by the resistor tends to be stable. As shown in FIG. 5, when there is direct current residual current, a waveform with up and down waveform being lateral stability appears. The actual sampling data of the circuit is shown in FIG. 6.

Using two states of excitation square wave, not only the direct current residual current may be detected, but also the alternating current residual current of partial frequency may be processed by algorithm analysis. Due to the high frequency of the injected square wave, even for alternating current signal, it can also be considered that the leakage current remains unchanged in one excitation half wave time, and according to the different responses generated by the hysteresis loop to different direct current, different leakage signal values are superimposed on the excitation square wave of a detection winding. The induction principle is the same as the direct current residual current detection principle. The signal is collected by the sampling resistor, the reproduction of the complex waveform may be completed through feature extraction, and the excitation square wave is a modulated signal relative to the signal to be detected. According to the sampling theorem, it that can be analyzed that the maximum frequency of the sensing signal is 1/5 of the excitation square wave frequency.

The induction current of the detection winding first passes through a PGA amplification circuit through the sampling resistor, then read by an ADC sampling module and inputted into an algorithm DSP unit for analysis.

Step 1: an internal circuit of the chip is controlled to make the coil and the resistor form a pure sensing measurement alternating current mode, at this time, the excitation voltage is 0, the duration is set to t2ms, the coil and the resistor are approximately directly connected. After passing through an operational amplifier circuit, the data is sampled by the ADC, and the sampled data is sent to a hardware algorithm DSP module for calculation and analysis through an algorithm, and then determined.

Step 2: the internal circuit of the chip is controlled, when the alternating current residual current detection is completed, to switch the working state and output the two states of positive and negative voltage, which are generated alternately and are approximately the positive and negative polarity of square wave excitation signals. At this time, the coil and the sampling resistor are superimposed with the excitation square wave, which makes the magnetic core work back and forth in the positive and negative saturation regions for t1ms of excitation duration. After passing through the operational amplifier circuit, the data is sampled by the ADC and the sampled data is sent to the hardware algorithm DSP module for calculation and analysis through the algorithm, and then determined.

Step 3: in the algorithm DSP module, there is a special switching control algorithm to prevent the detection time from being unable to meet the action requirements of the national standard due to the sudden large current. When the complex residual current detection is carried out in a certain state, if the sudden large current is found, an algorithm control module generates an interruption, and according to the specific sampled signal at this time, the type of sudden signal (large direct current, large alternating current, etc.) is analyzed. Combined with the detection state of working in alternating current/direct current at this time, the detection state is controlled to maintain t2/t1ms, or to immediately switch to the direct current/alternating current detection state, and the state is controlled to maintain t2/t1ms. After passing through the operational amplifier circuit, the data is sampled by the ADC and the sampled data is sent to the hardware algorithm DSP module for calculation and analysis through the algorithm, and then determined.

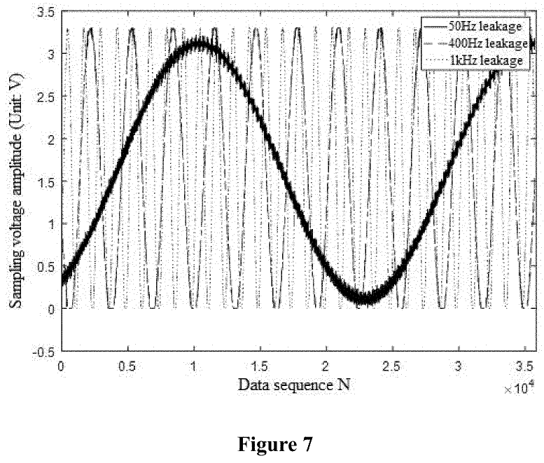

FIGS. 6 and 7 correspond to the actual sampling signals of the direct current residual current and the alternating current residual current, respectively. The final results can be obtained by means of algorithm feature extraction and analysis. It can be seen from the data in the figures that the actual effect is the same as the theoretical derivation.

The description above is only the preferred embodiment of the disclosure. For those skilled in the art, several improvements and changes can be made without departing from the principle of the present disclosure. Any modification, equivalent replacement, improvement, etc. made within the spirit and principle of the present disclosure shall be included in the protection of the present disclosure.

1. A method for detecting a residual current based on switching of working states of a magnetic core, the method comprising:
step 1: configuring, by a control chip, a detection state to be a pure induction mode with no voltage, keeping the pure induction mode for t1ms;
step 2: configuring, by the control chip, the detection state to be a mode of positive and negative saturation excitation square waves, keeping the mode of positive and negative saturation excitation square waves for t2ms;
step 3: when a duration of each mode ends, outputting a characteristic quantity based on sampling data through an algorithm module, and processing the characteristic quantity by a software to complete a state determination for a current time instant; and
step 4: in case of a sudden large current, adjusting the detection state to a new detection mode through a state control module, to respond to the sudden large current, and the software performing process after data collection is completed and a process performed by the algorithm module is completed.

2. The method for detecting a residual current based on switching of working states of a magnetic core according to claim 1, wherein
voltages with two states of saturation excitation in positive and negative directions are generated by using an H-bridge driving circuit, and a switching frequency is adjustable; a circuit is adjusted to the pure induction mode, and a sampling resistor and a coil are directly connected; an alternating current residual current and a direct current residual current are detected by switching among three states of positive voltage, negative voltage and no voltage.

3. The method for detecting a residual current based on switching of working states of a magnetic core according to claim 1, wherein
the magnetic core for detecting the residual current is permalloy or amorphous soft magnetic material with high permeability, low remanence and low coercivity.

4. The method for detecting a residual current based on switching of working states of a magnetic core according to claim 1, wherein step 2 comprises:
generating positive and negative saturation excitation voltages by using a H-bridge driving circuit and adjusting a switching frequency, to make a signal enter a saturation region of a hysteresis loop bidirectionally, wherein a direct current residual current generates different sensing signals in different regions of the hysteresis loop, different direct current residual currents are detected by using differences in the different sensing signals, and an actual direct current residual current is obtained by means of algorithm extraction, and an operation for the actual direct current residual current is performed.

5. The method for detecting a residual current based on switching of working states of a magnetic core according to claim 1, wherein
generating a group of excitation response signals by using a positive voltage and a negative voltage, performing data processing by collecting positive and negative response signals in one excitation period, and combining multiple excitation periods to determine the residual current.

6. The method for detecting a residual current based on switching of working states of a magnetic core according to claim 1, wherein
controlling, by the chip, the switching among three modes of the detection state, to detect a full waveform residual current, calculating a value of a signal corresponding to the full waveform residual current by means of algorithm processing, and processing the signal and performing an operation based on the processed signal.

7. The method for detecting a residual current based on switching of working states of a magnetic core according to claim 1, wherein step 4 includes:
responding to residual currents of different waveforms with a large amplitude in case of a sudden signal, identifying the sudden signal by the algorithm module, and switching the detection state by the state control module to collect and process the signal.
